(19) United States
(12) Patent Application Publication
(10) Pub. No.: US 2025/0336698 A1
(43) Pub. Date: Oct. 30, 2025

(54) TRAY FOR CARRYING A DEVICE BASED ON CONTACT LIMITED TO AN EDGE PORTION OF THE DEVICE

(71) Applicant: DELPHON INDUSTRIES, LLC, Hayward, CA (US)

(72) Inventor: Rajesh Kumar VARMA, Hayward, CA (US)

(21) Appl. No.: 18/797,473

(22) Filed: Aug. 7, 2024

Related U.S. Application Data
(60) Provisional application No. 63/640,099, filed on Apr. 29, 2024.

(51) Int. Cl. H01L 21/673

(52) U.S. Cl. CPC H01L 21/67336

(57) ABSTRACT

A tray for carrying a device based on contact limited to edge portions of the device is disclosed. The tray comprises an open frame comprising an outer frame portion, an inner frame portion, and a plurality of fingers, having a central opening, and made of a plastic, and a tacky layer made of a thermoplastic elastomer. The central opening has a central axis. The tacky layer comprises a plurality of tacky layer portions, each covering a finger. Each finger and the tacky layer portion covering each finger extend from the inner frame portion inwardly toward the central axis. The tacky layer portion covering each finger slopes downwardly at an angle of 0.5 to 20 degrees with respect to the upper surface of the inner frame portion. The tray is configured to carry a device on upper surfaces of the tacky layer portions covering two or more of the fingers.

### CROSS-REFERENCE TO RELATED APPLICATIONS

This application claims benefit of U.S. Provisional Application No. 63/640,099, filed Apr. 29, 2024, which is incorporated herein by reference.

### FIELD OF THE INVENTION

The present invention relates generally to trays for carrying a device based on contact limited to an edge portion of the device, and more particularly to trays for carrying a device based on contact limited to an edge portion of the device comprising (a) an open frame comprising an outer frame portion, an inner frame portion, and a plurality of fingers, having a central opening, and made of a plastic, and (b) a tacky layer made of a thermoplastic elastomer.

### BACKGROUND OF THE INVENTION

Devices such as semiconductor or photonic components are often temporarily secured on tacky or non-tacky carriers as they are transported from one process step to another. Tacky carriers include trays and boxes with laminated tape adhesives, such as Gel-Pak's Vacuum Release (VR) trays and AD series gel boxes. Non-tacky carriers include waffle packs, such as Gel-Pak's Lid/Clip Super System (LCS2) waffle pack, JEDEC trays, and tape and reel carriers.

Tacky carriers can be advantageous for transporting devices relative to non-tacky carriers. This is because placing devices on the tacky surface of a tacky carrier can immobilize the devices within the carrier and thus prevent damage from chipping and friction due to moving contact between the devices and the carrier during and between process steps.

This advantage can be compromised, though, during removal of the immobilized devices from tacky carriers. This is because removal of the immobilized devices from the surfaces of tacky carriers requires application of force, generally by an automated pick-up tool or alternatively by hand, to break the adhesion between the devices and the surfaces of tacky carriers. If the adhesion between devices and the surface of a tacky carrier is too strong, then the force required to remove the devices from the surface of the tacky carrier can be so great as to cause damage to the devices upon being picked up, or to cause an automated pick-up tool to fail to remove the devices from the surface of the tacky carrier at all.

Moreover, some devices include specific areas that are sensitive to adhesive removal force. Such areas include gold air bridges and other designated Keep Out Zones (KOZs). For these devices, the specific areas on the device must not be put in contact with adhesives.

Non-tacky carriers can be customized for carrying devices having specific sizes and shapes without relying on tacky surfaces. This can involve making carriers having pockets that have a size and shape complementary to the specific size and shape of a device to be carried. Customizing carriers necessitates creating different stock keeping units (SKUs) for each device dimension, though, resulting in many SKUs. Moreover, even with such customization devices still tend to experience some movement in pockets of customized carriers. This is because pockets cannot be made to provide an exact fit with devices. This can detrimentally generate plastic shavings and/or scratch the devices due to moving contact between the devices and the pockets of the customized carriers. This also can cause devices to lose their orientation within pockets.

Thus, a need exists for improved carriers that provide the advantages of tacky carriers by immobilizing devices within the carriers, thus preventing damage from chipping and friction, without the disadvantages of adhesion between the devices and the surface of a tacky carrier being so strong as to result in damage to the devices and/or failure of pickup, and undesirable contact with adhesives at specific areas of devices that are sensitive to adhesive removal force, and the advantages of customized non-tacky carriers in being designed to carry devices having specific shapes and sizes, without the disadvantages of expensive customization and moving contact between the devices and the pockets of the customized carriers.

### BRIEF SUMMARY OF THE INVENTION

A tray for carrying a device based on contact limited to an edge portion of the device is disclosed.

The tray comprises:
(a) an open frame comprising an outer frame portion, an inner frame portion, and a plurality of fingers, having a central opening, and made of a plastic; and
(b) a tacky layer made of a thermoplastic elastomer.

The open frame has an outer perimeter defined by the outer frame portion and an inner perimeter defined by the inner frame portion and the plurality of fingers.

The outer frame portion, the inner frame portion, and the plurality of fingers each have an upper surface and a lower surface.

The central opening has a central axis extending between the upper surfaces and the lower surfaces of the outer frame portion, the inner frame portion, and the plurality of fingers.

The tacky layer comprises a plurality of tacky layer portions.

Each tacky layer portion covers a finger of the plurality of fingers at the upper surface of the finger and has an upper surface and a lower surface.

The inner frame portion extends from the outer frame portion toward the central axis.

Each finger and the tacky layer portion covering each finger extend from the inner frame portion inwardly toward the central axis.

The tacky layer portion covering each finger slopes downwardly at an angle of 0.5 to 20 degrees with respect to the upper surface of the inner frame portion.

The tray is configured to carry a device on the upper surfaces of the tacky layer portions covering two or more of the fingers of the plurality of fingers based on contact between an edge portion of the device and the upper surfaces of the tacky layer portions covering the two or more of the fingers of the plurality of fingers.

In some embodiments, the open frame has a shape that is square, rectangular, or circular.

In some embodiments, the plastic comprises one or more of polystyrene (PS), polycarbonate (PC), low density polyethylene (LDPE), high density polyethylene (HDPE), ethylene vinyl acetate (EVA), polypropylene, or an engineering plastic. In some of these embodiments, the engineering plastic comprises one or more of polyoxymethylene (POM), acrylonitrile butadiene styrene (ABS), polyamide (PA), or polyethylene terephthalate (PET).

In some embodiments, each finger has an outer end and an inner end, and a length of 20% to 90% of the distance between the outer end and the central axis along the shortest distance between the outer end and the central axis. In some of these embodiments, each finger has a first side and a second side, and a width of 5% to 50% of the length of the finger along the shortest distance between the first side and the second side of the finger.

In some embodiments, the tacky layer portion covering each finger slopes downwardly at an angle of 0.6 to 10 degrees, 0.7 to 5 degrees, 0.8 to 4 degrees, 0.9 to 3 degrees, 1 to 2 degrees, 1.1 to 1.8 degrees, 1.2 to 1.6 degrees, 1.3 to 1.4 degrees, or 1.37 degrees with respect to the upper surface of the inner frame portion.

In some embodiments, the plurality of fingers comprises three to six fingers.

In some embodiments, the thermoplastic elastomer comprises one or more of thermoplastic olefin elastomer (e.g. copolymer of ethylene with one or more of propylene, butene, or octene), styrene-ethylene-butylene-styrene (SEBS), styrene-ethylene-propylene-styrene (SEPS), styrene-ethylene-ethylene-butylene-styrene (SEEBS), styrene-butadiene-styrene (SBS), styrene-isoprene-styrene (SIS), styrene-isobutylene-styrene (SIBS), poly(methyl methacrylate)-b-poly(n-butyl acrylate)-b-poly(methyl methacrylate) (PMMA-b-PnBA-b-PMMA), or ethylene vinyl acetate (EVA).

In some embodiments, the tacky layer portion covering each finger of the plurality of fingers has a surface tack on stainless steel as per ASTM D1000 of less than 3 ounces/inch.

In some embodiments, the tacky layer further comprises another tacky layer portion covering the inner frame portion at the upper surface of the inner frame portion.

In some embodiments, the outer frame portion is not covered by any portion of the tacky layer.

In some embodiments, the tacky layer has been applied directly to at least the plurality of fingers at the upper surface of the plurality of fingers.

In some embodiments, the tacky layer has been applied to at least the plurality of fingers by overmolding on at least the plurality of fingers.

In some embodiments, the plurality of fingers have radial symmetry about the central axis.

Also disclosed is a system for carrying a plurality of devices based on contact limited to edge portions of the devices, the system comprising a plurality of trays.

Each tray of the plurality of trays comprises:
(a) an open frame comprising an outer frame portion, an inner frame portion, and a plurality of fingers, having a central opening, and made of a plastic; and
(b) a tacky layer made of a thermoplastic elastomer.

The open frame has an outer perimeter defined by the outer frame portion and an inner perimeter defined by the inner frame portion and the plurality of fingers.

The outer frame portion, the inner frame portion, and the plurality of fingers each have an upper surface and a lower surface.

The central opening has a central axis extending between the upper surfaces and the lower surfaces of the outer frame portion, the inner frame portion, and the plurality of fingers. The tacky layer comprises a plurality of tacky layer portions.

Each tacky layer portion covers a finger of the plurality of fingers at the upper surface of the finger and has an upper surface and a lower surface.

The inner frame portion extends from the outer frame portion toward the central axis.

Each finger and the tacky layer portion covering each finger extend from the inner frame portion inwardly toward the central axis.

The tacky layer portion covering each finger slopes downwardly at an angle of 0.5 to 20 degrees with respect to the upper surface of the inner frame portion.

The tray is configured to carry a device on the upper surfaces of the tacky layer portions covering two or more of the fingers of the plurality of fingers based on contact between an edge portion of the device and the upper surfaces of the tacky layer portions covering the two or more of the fingers of the plurality of fingers.

Each tray of the plurality of trays is connected to at least one other tray of the plurality of trays.

### BRIEF DESCRIPTION OF THE DRAWINGS

These and other features, aspects, and advantages of the present disclosure are better understood when the following detailed description is read with reference to the accompanying drawings.

FIG. 1 is a first perspective view of a first embodiment of a tray for carrying a device based on contact limited to an edge portion of the device as disclosed herein. The tray comprises four fingers, each extending inwardly from a central position along a side of the inner frame portion, corresponding to a “+ configuration.”

FIG. 2 is a second perspective view of the tray of FIG. 1.

FIG. 3 is a top view of the tray of FIG. 1.

FIG. 4 is a bottom view of the tray of FIG. 1.

FIG. 5 is a front view of the tray of FIG. 1.

FIG. 6 is a back view of the tray of FIG. 1.

FIG. 7 is a first side view of the tray of FIG. 1.

FIG. 8 is a second side view of the tray of FIG. 1.

FIG. 9 is a sectional view of the tray of FIG. 1, viewed along the cutting plane shown in FIG. 3.

FIG. 10 is an expanded sectional view of the tray of FIG. 9, illustrating that a tacky layer portion 132 covering a finger 108 slopes downwardly at an angle 146 of 0.5 to 20 degrees with respect to the upper surface 118 of the inner frame portion 106 based on the two horizontal dashed lines being parallel, the two slanted dashed lines being parallel, and thus the two angles 146 being equal as shown.

FIG. 11 is a first perspective view of a second embodiment of a tray for carrying a device based on contact limited to an edge portion of the device as disclosed herein. The tray comprises four fingers, each extending inwardly from corners of the inner frame portion, corresponding to an “x configuration.”

FIG. 12 is a second perspective view of the tray of FIG. 11.

FIG. 13 is a top view of the tray of FIG. 11.

FIG. 14 is a bottom view of the tray of FIG. 11.

FIG. 15 is a front view of the tray of FIG. 11.

FIG. 16 is a back view of the tray of FIG. 11.

FIG. 17 is a first side view of the tray of FIG. 11.

FIG. 18 is a second side view of the tray of FIG. 11.

FIG. 19 is a sectional view of the tray of FIG. 11, viewed along the cutting plane shown in FIG. 13.

FIG. 20 is an expanded sectional view of the tray of FIG. 19.

FIG. 21 is a first perspective view of the first embodiment of a tray as shown in FIG. 1, corresponding to the “+ configuration,” reversibly securely holding a first exemplary device, corresponding to a circular device.

FIG. 22 is a second perspective view of the tray and device of FIG. 21.

FIG. 23 is a top view of the tray and device of FIG. 21.

FIG. 24 is a bottom view of the tray and device of FIG. 21.

FIG. 25 is a front view of the tray and device of FIG. 21.

FIG. 26 is another top view of the tray and device of FIG. 21.

FIG. 27 is a sectional view of the tray and device of FIG. 21, viewed along the cutting plane shown in FIG. 23.

FIG. 28 is an expanded sectional view of the tray and device of FIG. 27.

FIG. 29 is a first perspective view of the first embodiment of a tray as shown in FIG. 1, corresponding to the “+ configuration,” reversibly securely holding a second exemplary device, corresponding to a square device.

FIG. 30 is a top view of the tray and device of FIG. 29.

FIG. 31 is a bottom view of the tray and device of FIG. 29.

FIG. 32 is a front view of the tray and device of FIG. 29.

FIG. 33 is another top view of the tray and device of FIG. 29.

FIG. 34 is a sectional view of the tray and device of FIG. 29, viewed along the cutting plane shown in FIG. 30.

FIG. 35 is an expanded sectional view of the tray and device of FIG. 34.

FIG. 36 is a first perspective view of the first embodiment of a tray as shown in FIG. 1, corresponding to the “+ configuration,” reversibly securely holding a third exemplary device, corresponding to an oval device.

FIG. 37 is a top view of the tray and device of FIG. 36.

FIG. 38 is a bottom view of the tray and device of FIG. 36.

FIG. 39 is a front view of the tray and device of FIG. 36.

FIG. 40 is another top view of the tray and device of FIG. 36.

FIG. 41 is a sectional view of the tray and device of FIG. 36, viewed along the upper cutting plane shown in FIG. 37.

FIG. 42 is a sectional view of the tray and device of FIG. 36, viewed along the middle cutting plane shown in FIG. 37.

FIG. 43 is a sectional view of the tray and device of FIG. 36, viewed along the lower cutting plane shown in FIG. 37.

FIG. 44 is a top view of the second embodiment of a tray as shown in FIG. 11, corresponding to the “x configuration,” reversibly securely holding the first exemplary device, corresponding to a circular device.

FIG. 45 is a sectional view of the tray and device of FIG. 44, viewed along the upper cutting plane shown in FIG. 44.

FIG. 46 is an expanded sectional view of the tray and device of FIG. 45.

FIG. 47 is a sectional view of the tray and device of FIG. 44, viewed along the lower cutting plane shown in FIG. 44.

FIG. 48 is an expanded sectional view of the tray and device of FIG. 47.

FIG. 49 is a top view of a system including three trays as shown in FIG. 1, corresponding to the “+ configuration,” each reversibly securely holding a first exemplary device, corresponding to a circular device.

FIGS. 50-52 are top view images of exemplary trays as disclosed herein, corresponding to an “x” configuration, reversibly securely holding an exemplary circular device, an exemplary square device, and an exemplary oval device, respectively.

FIG. 53 is a perspective view of an exemplary tray as disclosed herein, corresponding to an “x” configuration, reversibly securely holding an exemplary oval device.

### DETAILED DESCRIPTION OF THE INVENTION

We have developed a tray for carrying devices that can reversibly securely hold a wide range of semiconductor and/or photonic devices that vary in size and shape based on contact limited to edge portions of the devices. This is based on the tray including an open frame including a plurality of fingers extending from an inner frame portion of the open frame and a tacky layer made of a thermoplastic elastomer that includes a plurality of tacky layer portions that cover each finger and slope downwardly at an angle of 0.5 to 20 degrees with respect to an upper surface of the inner frame portion. Considering the problems that adhesion between devices and the surface of a tacky carrier can be so strong as to result in damage to the devices and/or failure of pickup, that undesirable contact with adhesives at specific areas of devices that are sensitive to adhesive removal force should be avoided, that customization necessitates creating different SKUs for each device dimension, and that even with customization devices still tend to experience some movement in pockets of customized carriers, we decided to try making a carrier in which tacky contact between the carrier and devices would be limited to edge portions of devices. We recognized that thermoplastic elastomers are useful for reversibly securing devices to carriers. We also recognized that many semiconductor and photonic devices have a major surface that is generally flat or gently curved. We decided to try limiting the area of contact between a carrier and devices by designing a tray that includes an open frame including fingers that are covered with tacky layer portions made from a thermoplastic elastomer and that extend inwardly from an inner frame portion of the open frame. We realized that so long as a device has a major surface that is generally flat or gently curved and has a size and shape large enough to contact the tacky layer portions on at least two fingers when centered over the fingers and lowered onto the tacky layer portions, but not so large as to extend outwardly beyond the fingers to the inner frame portion, making the tacky layer portions covering the fingers slope downwardly at a shallow angle, centering the device over the fingers, and then lowering the device onto the tacky layer portions would result in contact between the tacky layer portions limited to an edge portion of the device. A wide range of devices can be reversibly securely held by the tray, from devices with sizes just slightly large enough to contact the tacky layer portions on at least two fingers when centered over the fingers and lowered onto the tacky layer portions, to devices not quite large enough to extend outwardly beyond the fingers to the inner frame portion, and including devices having profiles from a top view that are circular, square, oval, rectangular, curved, polygonal, stepped, bumped out, and/or irregular. The precise areas of contact will depend on the particular size and shape of the device. The tray can reversibly securely hold such devices without adhesion between devices and the surface of a tacky carrier being so strong as to result in damage to the devices and/or failure of pickup. The tray also can reversibly securely hold devices without adhesive contact with middle portions of major surfaces of the devices, and thus can avoid undesirable contact with adhesives at specific areas of devices that are sensitive to adhesive removal force. The tray can be used to reversibly securely hold a wide range of semiconductor and/or photonic devices that vary in size and shape without the need for customization. The tray prevents movement of a device relative to the tray when holding the device.

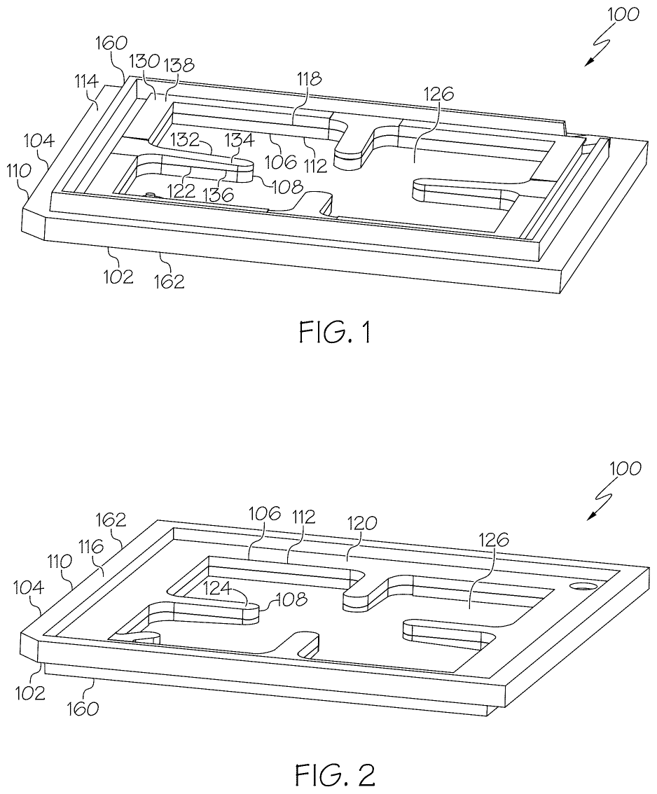

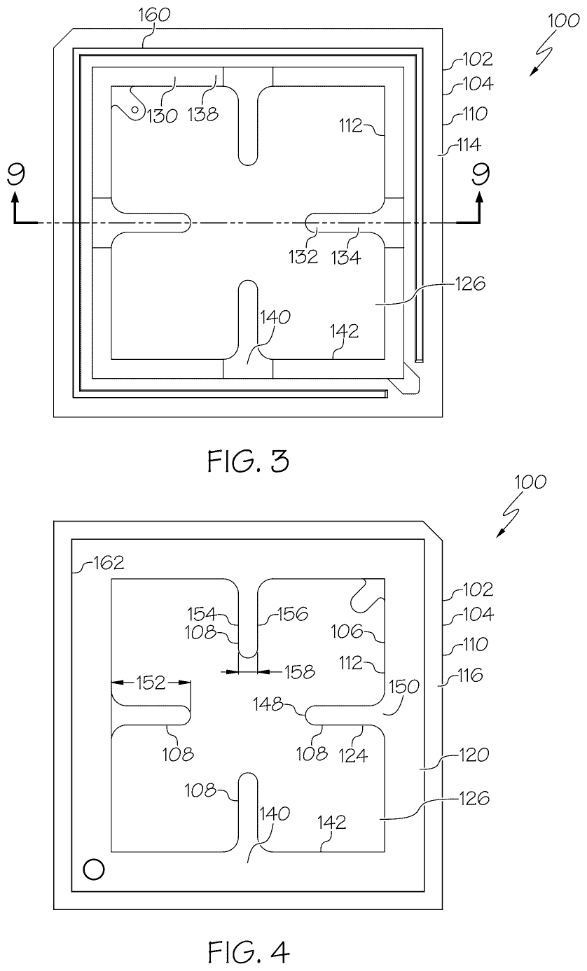

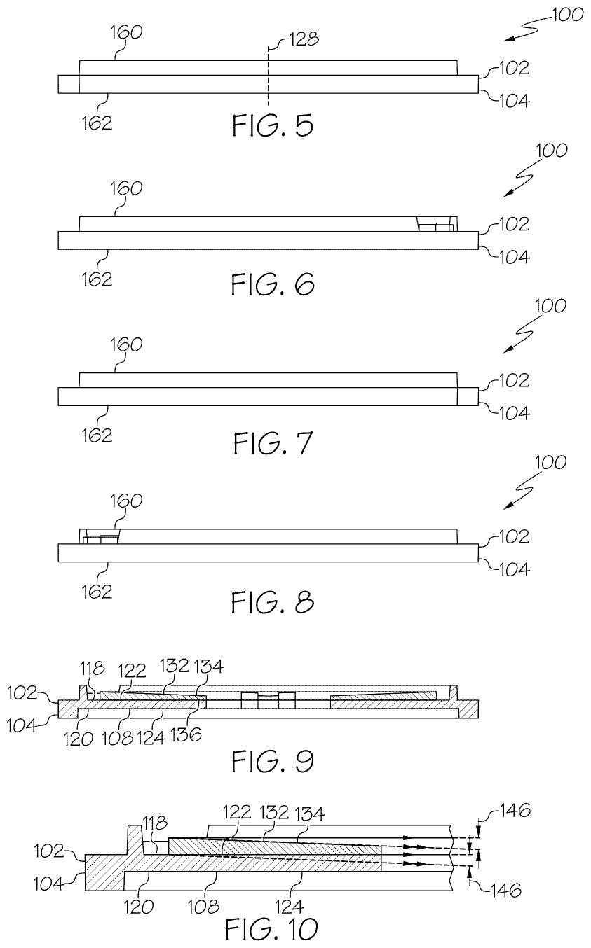

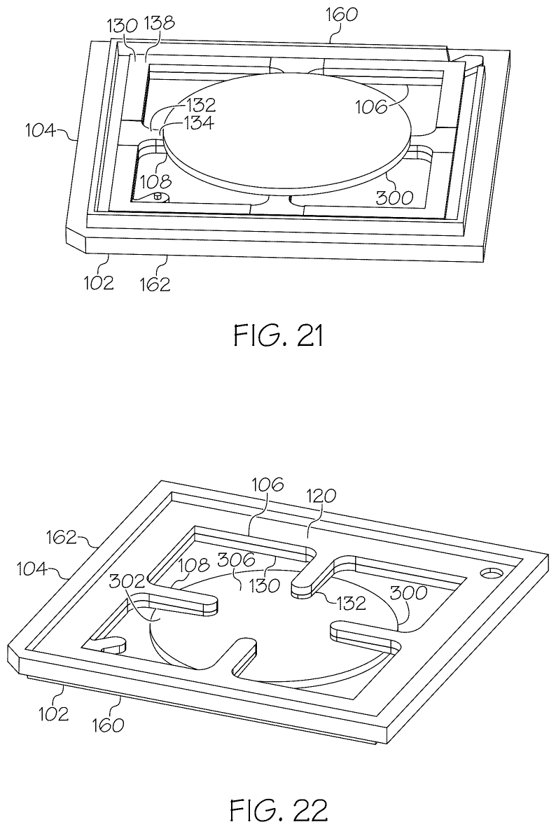

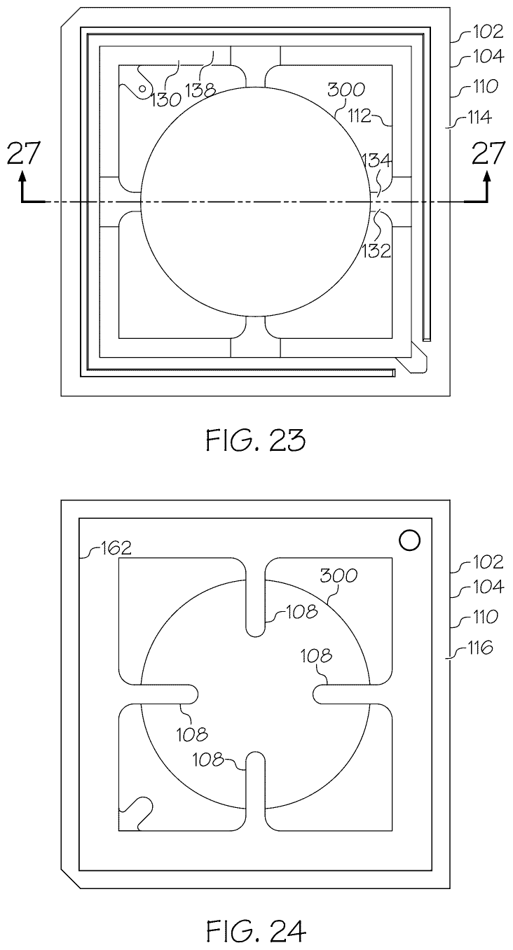

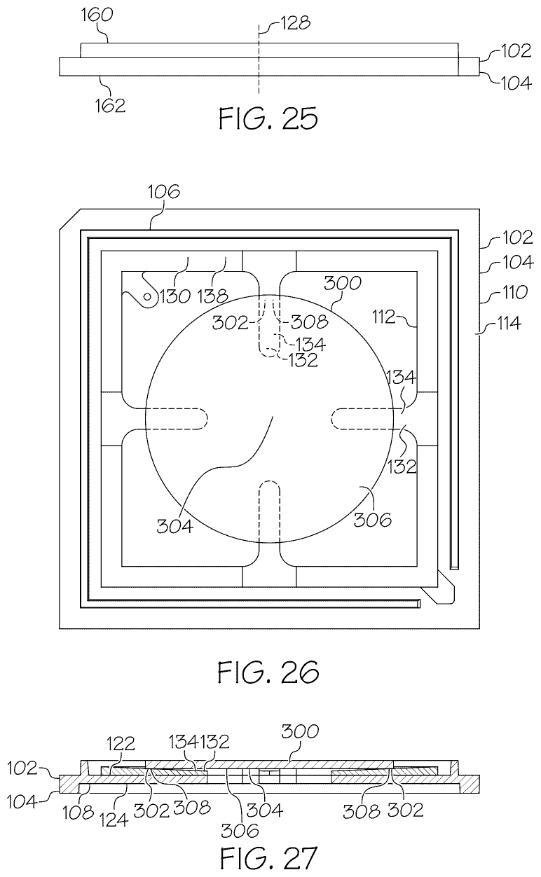

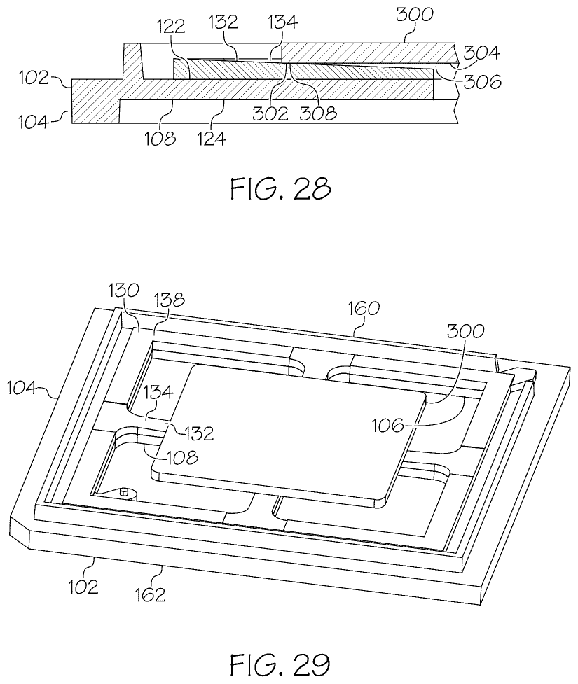

Accordingly, as shown in FIGS. 1-10, with reference to FIGS. 21-28, disclosed is a tray 100 for carrying a device 300 based on contact limited to an edge portion 302 of the device 300. The device 300 can be, for example, a semiconductor device, such as a wafer, a semiconductor material wafer, a silicon wafer, an integrated circuit wafer, a die, a semiconductor material die, a silicon die, and/or an integrated circuit die. The device 300 also can be, for example, a photonic device, such as a laser diode, a light-emitting diode, a solar cell, a photovoltaic cell, a display, an optical amplifier, or a photonic lens. The device 300 also can be another electronic device.

As shown in FIGS. 1-10, the tray comprises an open frame 102 comprising an outer frame portion 104, an inner frame portion 106, and a plurality of fingers 108.

The open frame 102 has an outer perimeter 110 defined by the outer frame portion 104 and an inner perimeter 112 defined by the inner frame portion 106 and the plurality of fingers 108. The outer frame portion 104 has an upper surface 114 and a lower surface 116. The inner frame portion 106 also has an upper surface 118 and a lower surface 120. The plurality of fingers 108 also each have an upper surface 122 and a lower surface 124.

The open frame 102 has a central opening 126. The central opening 126 has a central axis 128 extending between the upper surfaces 114, 118, 122 and the lower surfaces 116, 120, 124 of the outer frame portion 104, the inner frame portion 106, and the plurality of fingers 108.

The open frame 102 has a shape determined by the outer perimeter 110 of open frame 102. The open frame 102 can have a shape, for example, that is square, rectangular, or circular, from a top view, as determined by the outer perimeter 110 of the open frame 102.

The open frame 102 is made of a plastic. The plastic can be, for example, a semirigid plastic. This can be helpful for maintaining structural integrity of the open frame 102, and thus the tray 100, during manufacturing, shipment, storage, and use. The plastic can comprise, for example, one or more polymers such as polystyrene (PS), polycarbonate (PC), low density polyethylene (LDPE), high density polyethylene (HDPE), ethylene vinyl acetate (EVA), polypropylene, or an engineering plastic. The engineering plastic can comprise, for example, one or more of polyoxymethylene (POM), acrylonitrile butadiene styrene (ABS), polyamide (PA), or polyethylene terephthalate (PET). These polymers are useful for making a suitable semirigid plastic.

As shown in FIGS. 1-10, the tray 100 also comprises a tacky layer 130 made of a thermoplastic elastomer. This is in contrast, for example, to the tacky layer being made of an adhesive or a silicone elastomer.

Use of the thermoplastic elastomer provides advantages in this context, relative to use of an adhesive, based on differences between surface tack exhibited by thermoplastic elastomers versus adhesives. Tack may be considered as a measure of resistance to separation. Thermoplastic elastomers exhibit very low levels of surface tack in comparison to adhesives, because adhesives are generally formulated to include tackifying agents, e.g., up to 50% by weight, whereas thermoplastic elastomers are not. Indeed, for thermoplastic elastomers surface tack is generally so low that the surface tack does not offer any functional performance for commercial applications. Generally, for thermoplastic elastomer applications tack is an undesirable property. Accordingly, thermoplastic elastomer surfaces are typically modified to entirely eliminate tack. This can be done, for example, by applying a lubricant, (e.g. for dynamic seals, gaskets, or cap liners comprising elastomers), by creating surface texturing (e.g. for reduced contact with surfaces of materials comprising elastomers), or applying de-tackifying agents (e.g. for latex gloves or diaper films comprising elastomers).

Considering thermoplastic elastomers and adhesives in more detail, thermoplastic elastomers are elastic and offer high elongation and low hysteresis, whereas adhesives are viscous by nature and offer neither high elongation nor low hysteresis. So that adhesives may bond to various surfaces, adhesives are made from low molecular weight polymers. This allows adhesives to flow and build adhesive bonds. In contrast, thermoplastic elastomers are made from high molecular weight polymers. Thermoplastic elastomers maintain their shape and elasticity, rather than flowing. Adhesives must have relatively low modulus (Dahlquist criterion) to function, but thermoplastic elastomers do not have such strict limitations on modulus. The thermoplastic elastomer has a surface tack on stainless steel as per ASTM D1000 of less than 3 ounces/inch.

Making the tacky layer of a thermoplastic elastomer advantageously allows the tacky layer to stretch during placement of a device 300 onto the tacky layer 130, with the placement resulting in the tacky layer 130 conforming to the shape of the device 300, and peeling of the device 300 from the tacky layer 130, with initiation of separation of the device 300 from the tacky layer 130 occurring along an edge portion 302 of the device 300.

Use of a tacky layer 130 comprising a thermoplastic elastomer also provides advantages relative to use of a silicone elastomer. A tacky layer 130 that comprises a thermoplastic elastomer and that is substantially free of silicone advantageously can have a low surface energy and no silicone residue, making the tacky layer 130 useful for carriers of devices 300 that may experience negative chemical interactions with silicone.

The thermoplastic elastomer can comprise, for example, one or more of thermoplastic olefin elastomer (e.g. copolymer of ethylene with one or more of propylene, butene, or octene), styrene-ethylene-butylene-styrene (SEBS), styrene-ethylene-propylene-styrene (SEPS), styrene-ethylene-ethylene-butylene-styrene (SEEBS), styrene-butadiene-styrene (SBS), styrene-isoprene-styrene (SIS), styrene-isobutylene-styrene (SIBS), poly(methyl methacrylate)-b-poly(n-butyl acrylate)-b-poly(methyl methacrylate) (PMMA-b-PnBA-b-PMMA), or ethylene vinyl acetate (EVA).

As shown in FIGS. 1-10, the tacky layer 130 comprises a plurality of tacky layer portions 132. Each tacky layer portion 132 covers a finger 108 of the plurality of fingers 108 at the upper surface 122 of the finger 108. Each tacky layer portion 132 has an upper surface 134 and a lower surface 136. The tacky layer portions 132 can be formed by applying the tacky layer 130 to the upper surface 122 of the finger 108. The tacky layer 130 can be applied directly to at least the plurality of fingers 108 at the upper surface 122 of the plurality of fingers 108. The tacky layer 130 also can be applied to at least the plurality of fingers 108 by overmolding on at least the plurality of fingers 108.

As shown in FIGS. 1-10, the tacky layer 130 also can further comprise another tacky layer portion 138 covering the inner frame portion 106, at least partially, at the upper surface 118 of the inner frame portion 106. The tacky layer portion 138 covering the inner frame portion 106 can be continuous with one or more of the tacky layer portions 132 covering the fingers 108. For example, the tacky layer portion 138 covering the inner frame portion 106 can be continuous with all of the tacky layer portions 132 covering the fingers 108. This can be advantageous for ease of manufacturing of the tray 100, for example based on making an initial inner frame with the plurality of fingers 108 extending inwardly therefrom separately from an initial outer frame, applying the tacky layer 130 to the initial inner frame and the plurality of fingers 108 to cover the initial inner frame and the plurality of fingers 108, and then attaching the initial inner frame and the plurality of fingers 108, all covered with the tacky layer 130, to the initial outer frame, thereby forming the tray 100 comprising an open frame 102 comprising an outer frame portion 104, an inner frame portion 106, and a plurality of fingers 108, and a tacky layer 130 made of a thermoplastic elastomer.

As shown in FIGS. 1-10, the outer frame portion 104 can be provided such that it is not covered by any portion of the tacky layer 130. This can be advantageous for allowing stacking of trays 100 without having the trays 100 stick to each other at their respective outer frame portions 104.

As shown in FIGS. 1-10, the inner frame portion 106 extends from the outer frame portion 104 toward the central axis 128. In some examples the inner frame portion 106 is attached to the outer frame portion 104. Also in some examples the inner frame portion 106 is integral to the outer frame portion 104.

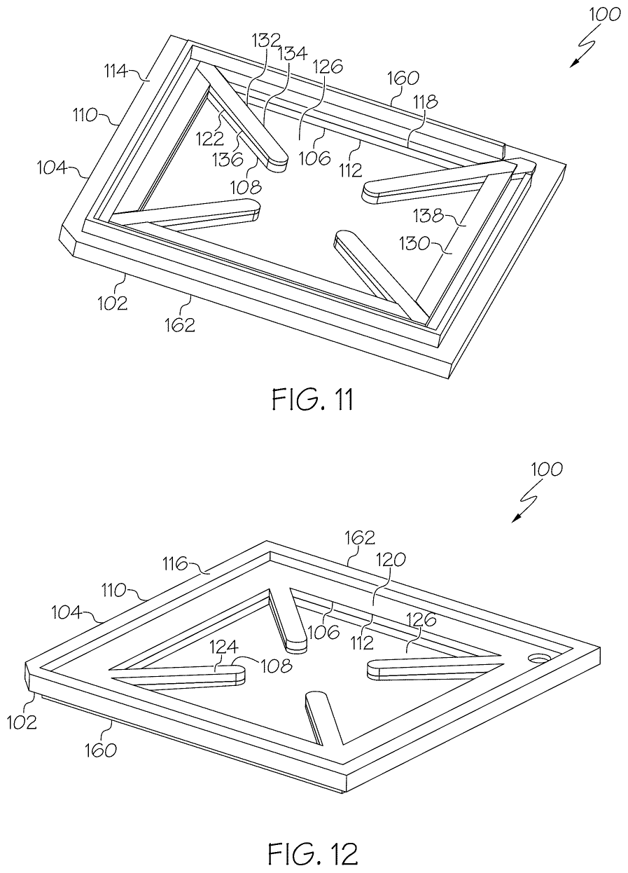

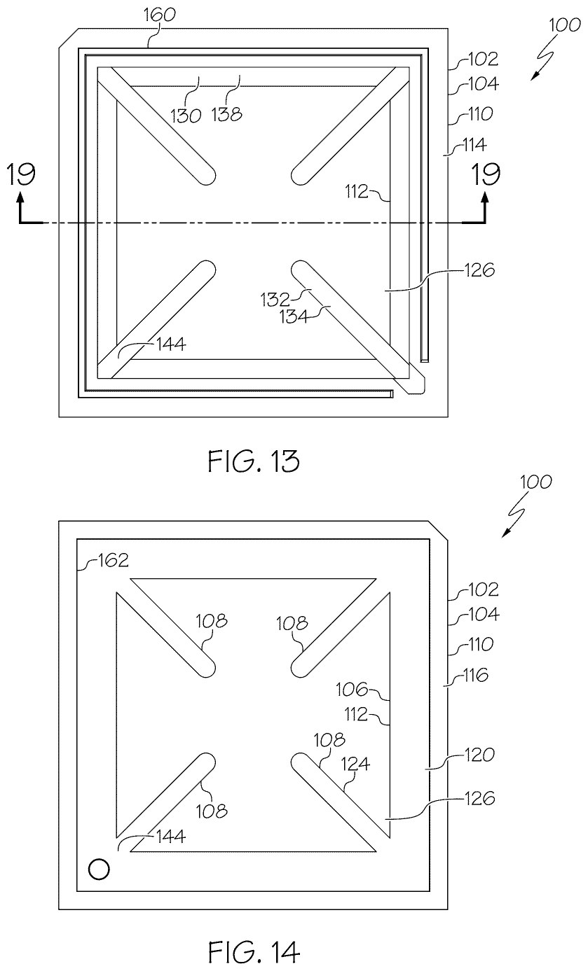

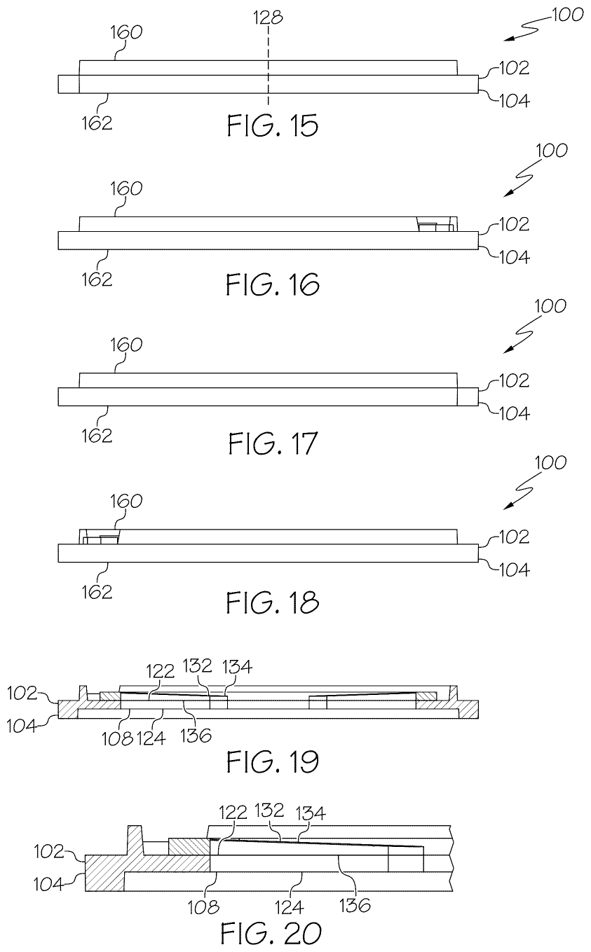

As shown in FIGS. 1-10, each finger 108 and the tacky layer portion 132 covering each finger 108 extend from the inner frame portion 106 inwardly toward the central axis 128. As shown in FIGS. 1-10, in some examples, the tray 100 comprises four fingers 108, each extending inwardly from a central position 140 along a side 142 of the inner frame portion 106, corresponding to a “+ configuration.” As shown in FIGS. 11-20, in some examples the tray 100 comprises four fingers 108, each extending inwardly from corners 144 of the inner frame portion 108, corresponding to an “x configuration.” Additional example trays 100 with different numbers of fingers 108 are discussed below. Additional example trays 100 in which the fingers 108 extend from other positions along a side 142 of the inner frame portion 106 also can be made.

As shown in FIG. 1, with reference to FIG. 9 and FIG. 10, the tacky layer portion 132 covering each finger 108 slopes downwardly at an angle 146 of 0.5 to 20 degrees with respect to the upper surface 118 of the inner frame portion 106.

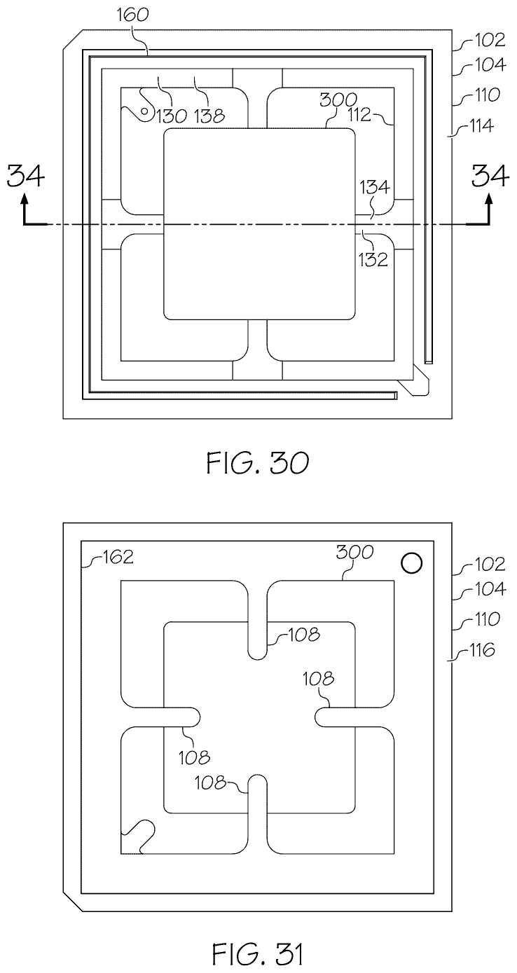

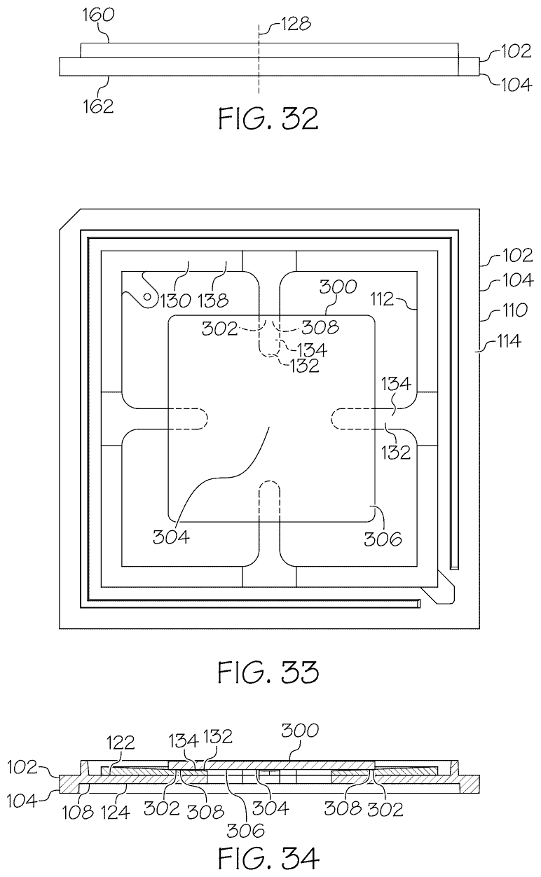

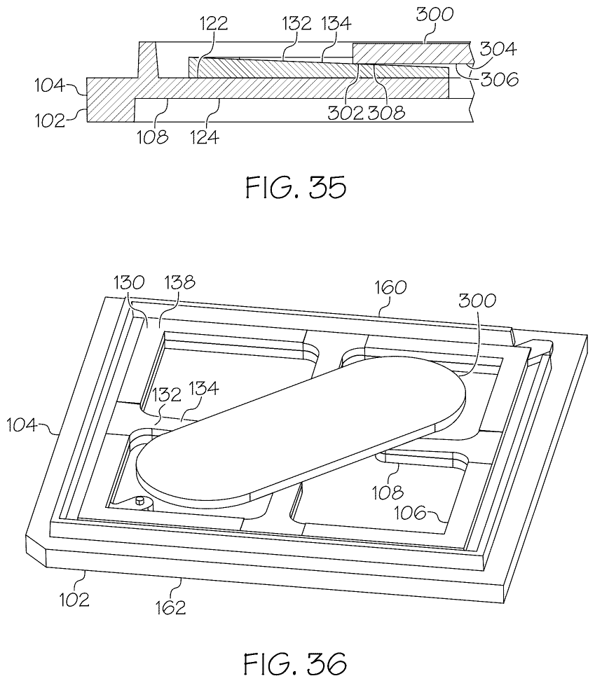

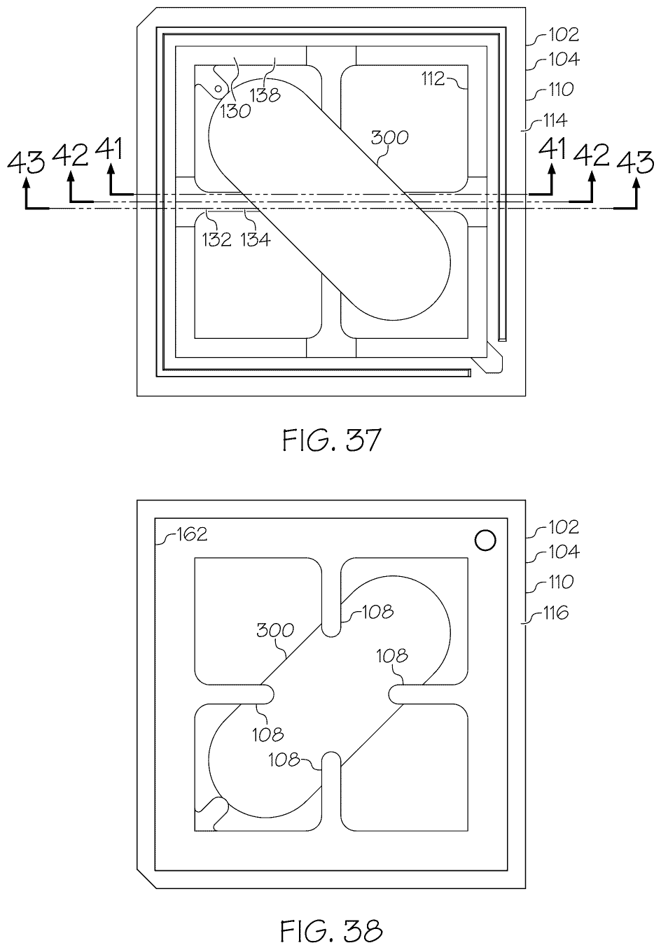

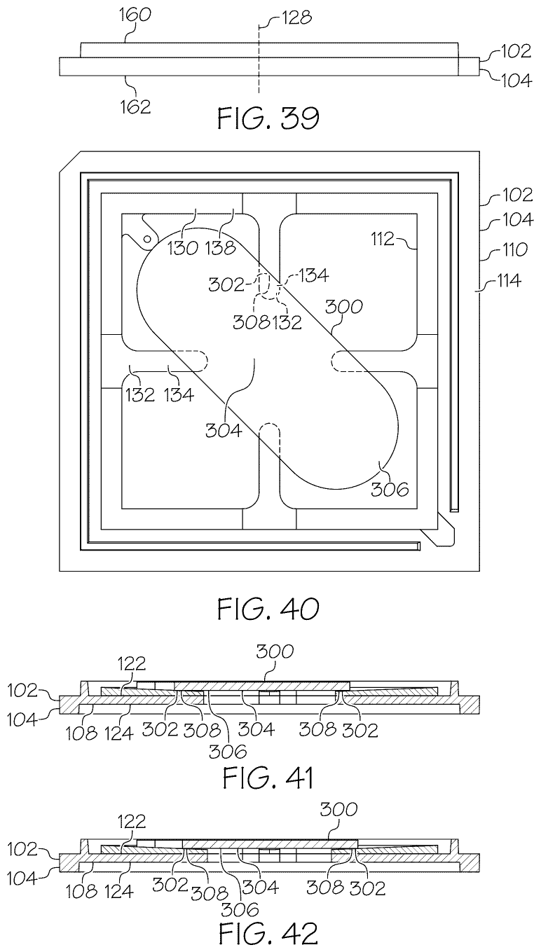

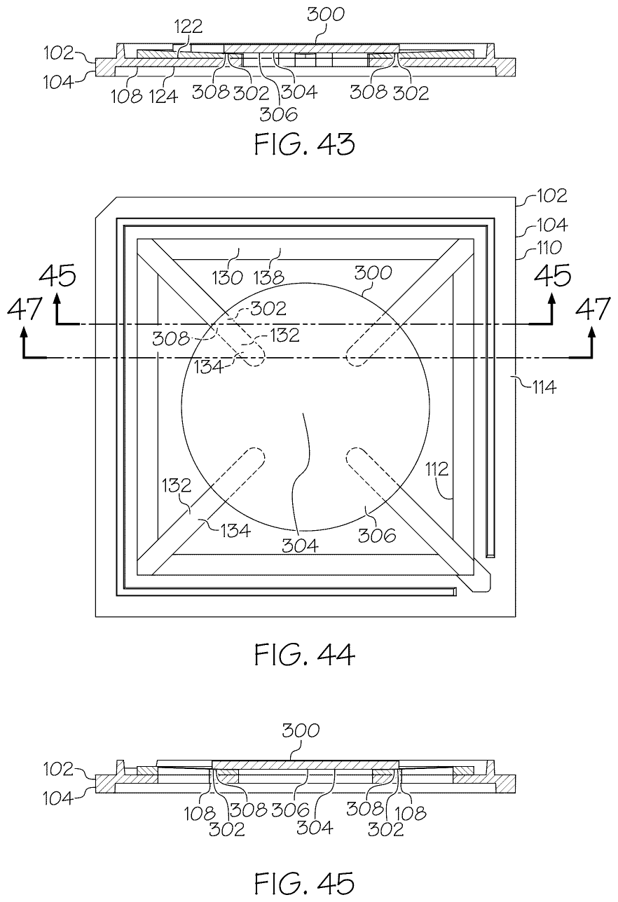

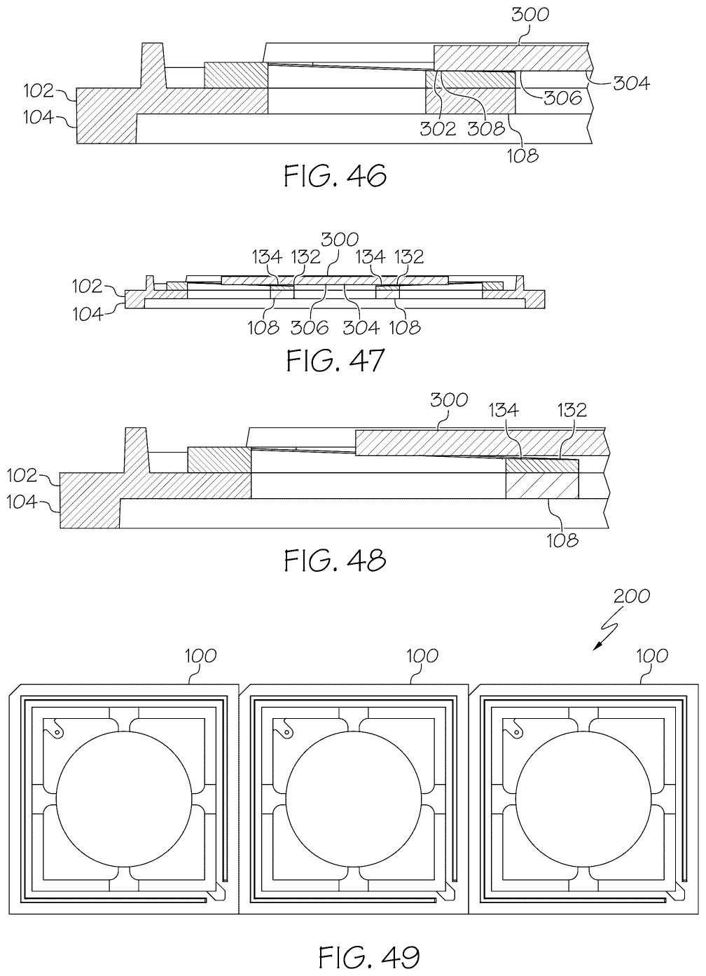

As shown in FIGS. 21-48, the tray 100 is configured to carry a device 300 on the upper surfaces 134 of the tacky layer portions 132 covering two or more of the fingers 108 of the plurality of fingers 108 based on contact between an edge portion 302 of the device 300 and the upper surfaces 134 of the tacky layer portions 132 covering the two or more of the fingers 108 of the plurality of fingers 108. As noted above, making the tacky layer 130 of a thermoplastic elastomer advantageously allows the tacky layer 130 to stretch during placement of a device 300 onto the tacky layer 130, with the placement resulting in the tacky layer 130 conforming to the shape of the device 300, and peeling of the device 300 from the tacky layer 130, with initiation of separation of the device 300 from the tacky layer 130 occurring along an edge portion 302 of the device 300. In the context of the tray 100 disclosed herein, this means that upon placement of a device 300 onto the upper surfaces 134 of the tacky layer portions 132 covering two or more of the fingers 108, the tacky layer portions 132 covering the two or more of the fingers 108 of the plurality of fingers 108 can stretch and conform to an edge portion 302 of the device 300, with contact limited to areas of contact 308 at the edge of portion 302.

Importantly, contact between the upper surfaces 134 of the tacky layer portions 132 covering two or more of the fingers 108 of the tray 100 and the device 300 is limited to an edge portion 302 of the device 300. Thus, the tray 100 can reversibly securely hold a device 300 without adhesive contact with a middle portion 304 of a major surface 306 of the device 300, and thus can avoid undesirable contact with adhesives at specific areas of the device 300 that may be sensitive to adhesive removal force.

As shown in FIGS. 21-28 and FIGS. 44-48, in some examples the device 300 can have a profile from a top view that is circular. As shown in FIGS. 29-35, in some examples the device 300 can have a profile from a top view that is square. As shown in FIGS. 36-43, in some examples the device 300 can have a profile from a top view that is oval. In further examples the device 300 can have a profile from a top view that is rectangular, curved, polygonal, stepped, bumped out, and/or irregular, among other profiles.

Considering the plurality of fingers 108 in more detail, the plurality of fingers 108 can comprise, for example, three to six fingers 108. Having at least three fingers 108 is helpful for stabilizing a device 300 while the device 300 is in contact with tacky layer portions 132 covering the three or more fingers 108. Having at least three fingers 108 also is helpful for preventing a device 300 from falling through the central opening 126 of the open frame 102, even while the device 300 is in contact with tacky layer portions 132 covering only two fingers 108. Having only up to six fingers 108 is generally helpful for avoiding excessive adhesion of the device 300 to the tacky layer portions 132.

Considering dimensions of the fingers 108, preferably the fingers 108 should have sufficient lengths and widths to provide substantial areas for contact between the tacky layer portions 132 covering the fingers 108 and an edge portion 302 of a device 300, without being so long or so wide as to intersect or interfere with each other. Each finger 108 can have, for example, an outer end 148 and an inner end 150, and a length 152 of 20% to 90% of the distance between the outer end 148 and the central axis 128 along the shortest distance between the outer end 148 and the central axis 128. Each finger 108 also can have, for example, a first side 154 and a second side 156, and a width 158 of 5% to 50% of the length 152 of the finger 108 along the shortest distance between the first side 154 and the second side 156 of the finger 108.

Considering the downward sloping angle 146 of the tacky layer portion 132 in more detail, the downward slope of the tacky layer portion 132 is important for making sure that the contact between the tacky layer portion 132 and the device 300 is limited to an edge portion 302 of the device 300, and for determining the extent to which the contact extends inwardly along a major surface 306 of the device 300, with a smaller angle 146 allowing for more extensive inwardly extending contact along the major surface 306. In some examples the tacky layer portion 132 covering each finger 108 slopes downwardly at an angle 146, for example, of 0.6 to 10 degrees, 0.7 to 5 degrees, 0.8 to 4 degrees, 0.9 to 3 degrees, 1 to 2 degrees, 1.1 to 1.8 degrees, 1.2 to 1.6 degrees, 1.3 to 1.4 degrees, or 1.37 degrees with respect to the upper surface 118 of the inner frame portion 106. Also in some examples the tacky layer portion 132 covering each finger slopes downwardly at an angle 146 of 0.5 to 10 degrees, 0.5 to 5 degrees, 0.5 to 4 degrees, 0.5 to 3 degrees, 0.5 to 2 degrees, 0.5 to 1 degree, 0.5 to 0.9 degrees, 0.5 to 0.8 degrees, 0.5 to 0.7 degrees, or 0.5 to 0.6 degrees with respect to the upper surface 118 of the inner frame portion 106. Also in some examples the tacky layer portion 132 covering each finger 108 slopes downwardly at an angle of 0.5, 0.6, 0.7, 0.8, 0.9, 1.0, 1.1, 1.2, 1.3, 1.4, 1.5, 1.6, 1.7, 1.8, 1.9, or 2.0 degrees with respect to the upper surface 118 of the inner frame portion 106. In some examples the tacky layer portions 132 covering each finger 108 slope downwardly at the same angle 146 as each other. In some examples the tacky layer portions 132 covering each finger 108 slope downwardly at different angles 146 than each other.

The plurality of fingers 108 can extend from the inner frame portion 106 in an orderly pattern. This can be advantageous for ease of manufacture of the tray 100 and ease of placement of devices 300 on the tacky layer portions 132 covering the fingers 108. The plurality of fingers 108 can, for example, have radial symmetry about the central axis 128.

In some examples, the open frame 102 can comprise one or more additional fingers 108 extending from the inner frame portion 106 inwardly toward the central axis 128, wherein the one or more additional fingers 108 each have an upper surface 122 and a lower surface 124, and the upper surface 122 of each of the one or more additional fingers 108 are not covered by a tacky layer portion 132.

Surface tack of the tacky layer portion 132 also is important for making sure that the contact between the tacky layer portion 132 and the device 300 is limited to an edge portion 302 of the device 300, and for determining the extent to which the contact extends inwardly along a major surface 306 of the device 300, with decreasing surface tack also allowing for more extensive inwardly extending contact along the major surface 306. The tacky layer portion 132 covering each finger 108 of the plurality of fingers 108 can have a surface tack on stainless steel as per ASTM D1000, for example, of less than 3 ounces/inch.

As shown in FIGS. 1-8, in some examples the inner frame portion 106 can comprise a rib portion 160 projecting upwardly from the upper surface 118 of the inner frame portion 106, and the outer frame portion 104 can comprise a flange portion 162 projecting downwardly from the lower surface 114 of the outer frame portion 104. In these examples, the rib portion 160 can fit within the flange portion 162. This can be useful for making the trays 100 stackable.

Also disclosed is a system 200 for carrying a plurality of devices 300 based on contact limited to edge portions 302 of the devices 300. As shown in FIG. 49, the system 200 comprises a plurality of trays 100 as described above. Each tray 100 of the plurality of trays 100 is connected to at least one other tray 100 of the plurality of trays 100. The plurality of trays 100 can be provided, for example, in formats such as JEDEC trays, matrix trays, and round trays, having diameters of 100 mm, 200 mm, or 300 mm, among other formats.

### EXAMPLES

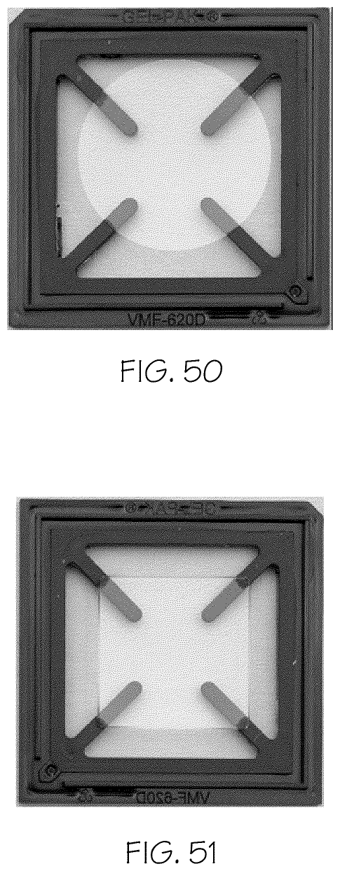

A prototype tray as disclosed herein including four fingers, each extending inwardly from corners of the inner frame portion, corresponding to an “x configuration,” is shown in FIGS. 50-53. The tray includes an open frame including an outer frame portion, an inner frame portion, and four fingers, having a central opening, and made of a plastic. The outer frame portion has an outer length of 50.80 mm (2.00 inches) and an outer width of 50.80 mm (2.00 inches). The four fingers each have widths of 2.50 mm (0.0984 inches). The tray also includes a tacky layer made of a thermoplastic elastomer. The tacky layer comprises four tacky layer portions. Each of the four tacky layer portions covers a finger at the upper surface of the finger and has an upper surface and a lower surface. Each of the four tacky layer portions covering each finger slopes downwardly at an angle of 1.37 degrees with respect to the upper surface of the inner frame portion.

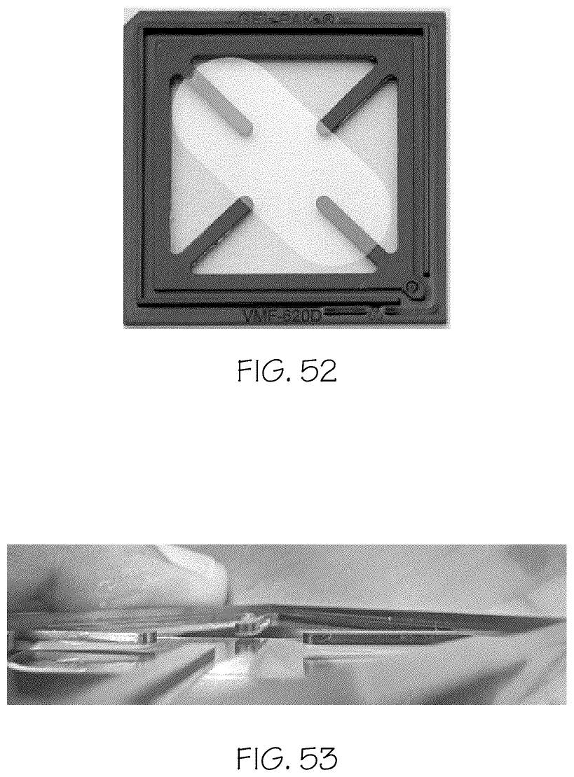

The prototype tray is shown reversibly securely holding a circular device, a square device, and an oval device in FIGS. 50-52, respectively. The prototype tray is doing this based on contact limited to an edge portion of each device, corresponding to small areas of wetting of the devices seen in FIGS. 50-52 where the edge of each device makes contact with two or more fingers. Specifically, the circular device and the square device make contact at four small areas of wetting, one at each of the fingers of the tray, as shown in FIG. 50 and FIG. 51, respectively. In contrast, as shown in FIG. 52, the oval device makes contact at two small areas of wetting, one at the finger in the top left of the view and the other at the finger at the bottom right of the view. This also can be seen in FIG. 53, which shows the oval device making contact with the finger on the left of the view, near the edge of the oval device, but not making contact with either of the fingers in the middle of the view.

As can be seen, the areas of contact for each device depend on the size and shape of the device. Accordingly, a wide range of devices can be reversibly securely held by the prototype tray, from devices with sizes just slightly large enough to contact the tacky layer portions on at least two fingers when centered over the fingers and lowered onto the tacky layer portions, to devices not quite large enough to extend outwardly beyond the fingers to the inner frame portion, and including devices having profiles from a top view that are circular, square, oval, rectangular, curved, polygonal, stepped, bumped out, and/or irregular. The precise areas of contact will depend on the particular size and shape of the device.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention.

1. A tray for carrying a device based on contact limited to an edge portion of the device comprising:
(a) an open frame comprising an outer frame portion, an inner frame portion, and a plurality of fingers, having a central opening, and made of a plastic; and
(b) a tacky layer made of a thermoplastic elastomer, wherein:
the open frame has an outer perimeter defined by the outer frame portion and an inner perimeter defined by the inner frame portion and the plurality of fingers;
the outer frame portion, the inner frame portion, and the plurality of fingers each have an upper surface and a lower surface;
the central opening has a central axis extending between the upper surfaces and the lower surfaces of the outer frame portion, the inner frame portion, and the plurality of fingers;
the tacky layer comprises a plurality of tacky layer portions;
each tacky layer portion covers a finger of the plurality of fingers at the upper surface of the finger and has an upper surface and a lower surface;
the inner frame portion extends from the outer frame portion toward the central axis;
each finger and the tacky layer portion covering each finger extend from the inner frame portion inwardly toward the central axis;
the tacky layer portion covering each finger slopes downwardly at an angle of 0.5 to 20 degrees with respect to the upper surface of the inner frame portion; and
the tray is configured to carry a device on the upper surfaces of the tacky layer portions covering two or more of the fingers of the plurality of fingers based on contact between an edge portion of the device and the upper surfaces of the tacky layer portions covering the two or more of the fingers of the plurality of fingers.

2. The tray according to claim 1, wherein the open frame has a shape that is square, rectangular, or circular.

3. The tray according to claim 1, wherein the plastic comprises one or more of polystyrene (PS), polycarbonate (PC), low density polyethylene (LDPE), high density polyethylene (HDPE), ethylene vinyl acetate (EVA), polypropylene, or an engineering plastic.

4. The tray according to claim 3, wherein the engineering plastic comprises one or more of polyoxymethylene (POM), acrylonitrile butadiene styrene (ABS), polyamide (PA), or polyethylene terephthalate (PET).

5. The tray according to claim 1, wherein each finger has an outer end and an inner end, and a length of 20% to 90% of the distance between the outer end and the central axis along the shortest distance between the outer end and the central axis.

6. The tray according to claim 5, wherein each finger has a first side and a second side, and a width of 5% to 50% of the length of the finger along the shortest distance between the first side and the second side of the finger.

7. The tray according to claim 1, wherein the tacky layer portion covering each finger slopes downwardly at an angle of 0.6 to 10 degrees with respect to the upper surface of the inner frame portion.

8. The tray according to tray 1, wherein the plurality of fingers comprises three to six fingers.

9. The tray according to claim 1, wherein the thermoplastic elastomer comprises one or more of thermoplastic olefin elastomer, a thermoplastic olefin elastomer copolymer of ethylene with one or more of propylene, butene, or octene, styrene-ethylene-butylene-styrene (SEBS), styrene-ethylene-propylene-styrene (SEPS), styrene-ethylene-ethylene-butylene-styrene (SEEBS), styrene-butadiene-styrene (SBS), styrene-isoprene-styrene (SIS), styrene-isobutylene-styrene (SIBS), poly(methyl methacrylate)-b-poly(n-butyl acrylate)-b-poly(methyl methacrylate) (PMMA-b-PnBA-b-PMMA), or ethylene vinyl acetate (EVA).

10. The tray according to claim 1, wherein the tacky layer portion covering each finger of the plurality of fingers has a surface tack on stainless steel as per ASTM D1000 of less than 3 ounces/inch.

11. The tray according to claim 1, wherein the tacky layer further comprises another tacky layer portion covering the inner frame portion at the upper surface of the inner frame portion.

12. The tray according to claim 1, wherein the outer frame portion is not covered by any portion of the tacky layer.

13. The tray according to claim 1, wherein the tacky layer has been applied directly to at least the plurality of fingers at the upper surface of the plurality of fingers.

14. The tray according to claim 1, wherein the tacky layer has been applied to at least the plurality of fingers by overmolding on at least the plurality of fingers.

15. The tray according to claim 1, wherein the plurality of fingers have radial symmetry about the central axis.

16. The tray according to claim 1, wherein the inner frame portion comprises a rib portion projecting upwardly from the upper surface of the inner frame portion, the outer frame portion comprises a flange portion projecting downwardly from the lower surface of the outer frame portion, and the rib portion fits within the flange portion.

17. A system for carrying a plurality of devices based on contact limited to edge portions of the devices, the system comprising a plurality of trays according to claim 1, wherein each tray of the plurality of trays is connected to at least one other tray of the plurality of trays.
